(19) United States
(12) Patent Application Publication
(10) Pub. No.: US 2009/0052489 A1
(43) Pub. Date: Feb. 26, 2009

(54) NITRIDE-BASED SEMICONDUCTOR LASER DEVICE AND METHOD OF MANUFACTURING THE SAME

(75) Inventor: Yasuhiko Nomura, Osaka-shi (JP)

Correspondence Address: DITTHAVONG MORI & STEINER, P.C., 918 Prince St., Alexandria, VA, 22314, US

(73) Assignee: Sanyo Electric Co., Ltd., Moriguchi-shi (JP)

(21) Appl. No.: 12/130,551

(22) Filed: May 30, 2008

(30) Foreign Application Priority Data
May 30, 2007 (JP) 2007-143784

(51) Int. Cl. H01S 5/323; H01L 33/00

(52) U.S. Cl. 372/49.01; 438/46; 257/E33.023; 257/E33.067

(57) ABSTRACT

A nitride-based semiconductor laser device includes a front facet located on a forward end of an optical waveguide and formed by a substantially (000-1) plane of a nitride-based semiconductor layer and a rear facet located on a rear end of the optical waveguide and formed by a substantially (0001) plane of the nitride-based semiconductor layer, wherein an intensity of a laser beam emitted from the front facet is rendered larger than an intensity of a laser beam emitted from the rear facet.

### CROSS-REFERENCE TO RELATED APPLICATIONS

The priority application number JP2007-143784, Nitride-Based Semiconductor Laser Device and Method of Manufacturing the Same, May 30, 2007, Yasuhiko Nomura, upon which this patent application is based is hereby incorporated by reference.

### BACKGROUND OF THE INVENTION

1. Field of the Invention

The present invention relates to a nitride-based semiconductor laser device and a method of manufacturing the same.

2. Description of the Background Art

A nitride-based semiconductor laser device and a method of manufacturing the same are known in general.

A nitride-based semiconductor laser device having the plane orientation of a main surface of an active layer formed by a substantially (H, K, −H−K, 0) plane (when at least either one of H and K is a nonzero integer) such as a (11-20) plane or a (1-100) plane, and capable of reducing a piezoelectric field caused in the active layer and increasing luminous efficiency is disclosed in general. In this conventional nitride-based semiconductor laser device, a (0001) plane and a (000-1) plane are formed as a pair of cavity facets, whereby gain of the nitride-based semiconductor laser device can be increased.

In the conventional nitride-based semiconductor laser device, however, the (0001) plane, one of the pair of cavity facets is a Ga-polar face while the (000-1) plane, the other thereof is an N-polar face. When the nitride-based semiconductor laser device is operated for a long time while employing the (0001) plane as a main laser emitting surface for example, an oxide film containing Ga is disadvantageously formed on the (0001) plane. Thus, the reflectance of the (0001) plane gradually changes with the long operation. Consequently, laser characteristics is disadvantageously unstable when the nitride-based semiconductor laser device is operated for a long time.

### SUMMARY OF THE INVENTION

In order to attain the aforementioned object, the inventor has found as a result of a deep study that stability of a laser device in a long time operation can be improved when a laser emitting surface of a nitride-based semiconductor laser device is a (000-1) plane. In other words, a nitride-based semiconductor laser device according to a first aspect comprises an optical waveguide extending substantially parallel to a [0001] direction of a nitride-based semiconductor layer, a front facet located on a forward end of the optical waveguide and formed by a substantially (000-1) plane of the nitride-based semiconductor layer and a rear facet located on a rear end of the optical waveguide and formed by a substantially (0001) plane of the nitride-based semiconductor layer, wherein an intensity of a laser beam emitted from the front facet is rendered larger than an intensity of a laser beam emitted from the rear facet.

A method of manufacturing a nitride-based semiconductor laser device according to a second aspect comprises steps of growing a nitride-based semiconductor element layer on a substrate, forming an optical waveguide extending substantially parallel to a [0001] direction on the nitride-based semiconductor element layer, forming a front facet formed by a substantially (000-1) plane of the nitride-based semiconductor layer on a forward end of the optical waveguide and forming a rear facet formed by a substantially (0001) plane of the nitride-based semiconductor layer on a rear end of the optical waveguide, wherein a direction substantially perpendicular to the [0001] direction of the nitride-based semiconductor layer substantially coincides with the normal direction of the substrate, and an intensity of a laser beam emitted from the front facet is larger than an intensity of a laser beam emitted from the rear facet.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view of a surface parallel to an optical waveguide of a semiconductor laser device, for schematically illustrating a structure of a nitride-based semiconductor laser device of the present invention;

FIG. 2 is a sectional view of a surface perpendicular to the optical waveguide of the semiconductor laser device, for schematically illustrating the structure of the nitride-based semiconductor laser device shown in FIG. 1;

FIG. 3 is a sectional view of a surface parallel to an optical waveguide of a semiconductor laser device, for illustrating a structure of a nitride-based semiconductor laser device according to a first embodiment of the present invention;

FIG. 4 is a sectional view of a surface perpendicular to the optical waveguide of the semiconductor laser device, for schematically illustrating the structure of the nitride-based semiconductor laser device according to the first embodiment of the present invention;

FIG. 5 is a sectional view of a surface parallel to an optical waveguide of a semiconductor laser device, for illustrating a structure of a nitride-based semiconductor laser device according to a second embodiment of the present invention;

FIG. 6 is a sectional view of a surface perpendicular to the optical waveguide of the semiconductor laser device, for schematically illustrating the structure of the nitride-based semiconductor laser device according to the second embodiment of the present invention;

FIG. 7 is a sectional view for illustrating a structure of a nitride-based semiconductor laser device according to a third embodiment of the present invention;

FIG. 8 is a plan view for illustrating a step of preparing the nitride-based semiconductor laser device shown in FIG. 7 by cleavage;

FIG. 9 is a sectional view showing a structure of a nitride-based semiconductor laser apparatus according to the third embodiment of the present invention; and

FIG. 10 is a plan view of illustrating a step of preparing a nitride-based semiconductor laser device according to a fourth embodiment of the present invention by etching.

### DESCRIPTION OF THE PREFERRED EMBODIMENTS

Embodiments of the present invention will be hereinafter described with reference to the drawings.

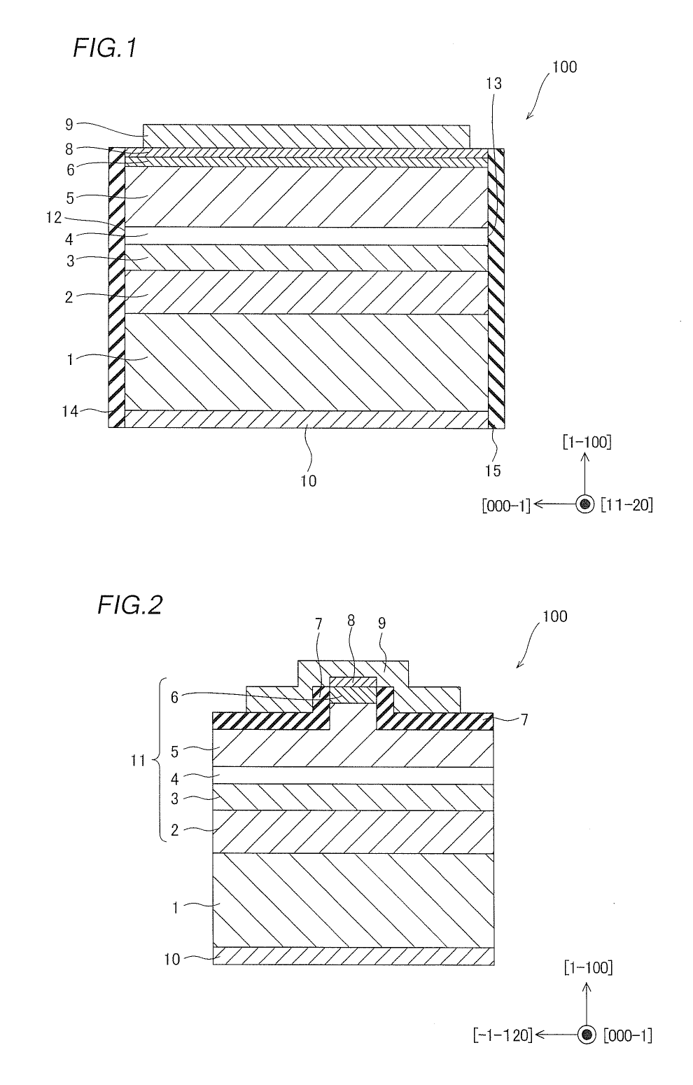

First, a concept of a nitride-based semiconductor laser device 100 of the present invention is described with reference to FIGS. 1 and 2, before specifically illustrating the embodiments of the present invention.

In the nitride-based semiconductor laser device 100 of the present invention, a first semiconductor layer 2 is formed on an upper surface of a substrate 1 as shown in FIG. 1. The first semiconductor layer 2 is a buffer layer made of GaN, for example. A first cladding layer 3 is formed on an upper surface of the first semiconductor layer 2. An emission layer 4 is formed on an upper surface of the first cladding layer 3. The first cladding layer 3 is formed by a nitride-based semiconductor having a band gap larger than the emission layer 4. A light guide layer having an intermediate band gap between those of the first cladding layer 3 and the emission layer 4 may be formed between the first cladding layer 3 and the light guide layer 4.

A second semiconductor layer 5 is formed on an upper surface of the emission layer 4. The second semiconductor layer 5 is formed by a second cladding layer having a band gap larger than the emission layer 4. The second semiconductor layer 5 has a conductivity type opposite to the first semiconductor layer 2. In particular, GaN, AlGaN or the like is employed as the first cladding layer 3 and the second semiconductor layer 5 (second cladding layer). A light guide layer having an intermediate band gap between those of the emission layer 4 and the second semiconductor layer 5 may be formed between the emission layer 4 and the second semiconductor layer 5.

As shown in FIG. 2, a contact layer 6 is formed on an upper surface of the second semiconductor layer 5. The contact layer 6 preferably has a band gap smaller than the second semiconductor layer 5. Current blocking layers 7 made of a dielectric material such as SiO₂ for confining a current and light in an emission region are formed on side surfaces of a ridge portion formed by the second semiconductor layer 5 and the contact layer 6. An ohmic electrode 8 is formed on an upper surface of the contact layer 6. A pad electrode 9 is formed on upper surfaces of the current blocking layers 7 and the ohmic electrode 8. An n-side electrode 10 is formed on a lower surface of the substrate 1.

The emission layer 4 may be undoped or doped with Si or the like. In particular, InGaN is employed as a material of the emission layer 4. The emission layer 4 is formed by a single layer, a single quantum well (SQW) structure or a multiple quantum well (MQW) structure.

In this case, the plane orientation of a main surface of the emission layer 4 is a substantially (H, K, —H—K, 0) plane (when at least either one of H and K is a nonzero integer) such as a (11-20) plane or a (1-100) plane. According to this structure, a piezoelectric field caused in the emission layer 4 can be reduced and hence luminous efficiency of the semiconductor laser element portion 11 (see FIG. 2) formed by the first semiconductor layer 2, the first cladding layer 3, the emission layer 4, the second semiconductor layer 5 and the contact layer 6 can be improved.

As shown in FIGS. 1 and 2, the ridge portion formed by the second semiconductor layer 5 and the contact layer 6 forms an optical waveguide structure in the semiconductor laser element portion 11. Although not shown, a method of forming the optical waveguide structure is not restricted to a method of forming the ridge portion, but the optical waveguide structure may be formed by a buried heterostructure.

This optical waveguide structure is formed substantially parallel to a [0001] direction and has a light emitting surface (front facet) 12 formed by side end surfaces of the first semiconductor layer 2, the first cladding layer 3, the emission layer 4, the second semiconductor layer 5 and the contact layer 6 on a front surface of the optical waveguide. The optical waveguide structure also has a light reflecting surface (rear facet) 13 formed by side end surfaces of the first semiconductor layer 2, the first cladding layer 3, the emission layer 4, the second semiconductor layer 5 and the contact layer 6 on a rear surface of the optical waveguide.

According to the first embodiment, the light emitting surface 12 is a substantially (000-1) plane having a polarity of a group V element such as a nitrogen (N) polarity and the light reflecting surface 13 is a substantially (0001) plane having a polarity of a group III element such as a Ga-polarity. The light emitting surface 12 and the light reflecting surface 13 are formed by etching such as dry etching, or cleavage or polishing. Facets formed by selective growth may be employed as the light emitting surface 12 and the light reflecting surface 13. The light emitting surface 12 and the light reflecting surface 13 may be formed by the same method or different methods. For example, a facet formed by selective growth may be employed as the light emitting surface 12 while the light reflecting surface 13 may be formed by etching. According to the first embodiment, the semiconductor laser element portion 11 is formed such that the intensity of a laser beam emitted from the light emitting surface 12 is larger than the intensity of a laser beam emitted from the light reflecting surface 13.

When at least one of the light emitting surface 12 and the light reflecting surface 13 is formed by cleavage, the plane orientation of the main surface of the emission layer 4 is preferably in the range of about ±0.3 degrees from the (H, K, −H−K, 0) plane. The plane orientations of the light emitting surface 12 and the light reflecting surface 13 formed by cleavage are preferably in the range of about ±0.3 degrees from the (000-1) plane and the (0001) plane respectively. Both of the light emitting surface 12 and the light reflecting surface 13 can be formed by a method other than etching, polishing or cleavage such as selective growth. When the light emitting surface 12 and the light reflecting surface 13 are formed by etching, the light emitting surface 12 and the light reflecting surface 13 may be formed by separate steps. At this time, the condition of dry etching in forming the light emitting surface 12 and the condition of dry etching in forming the light reflecting surface 13 are preferably different from each other.

For example, a first dielectric film 14 and a second dielectric film 15 such as Al₂O₃ or SiO₂ are formed on surfaces of the light emitting surface 12 and the light reflecting surface 13 respectively as shown in FIG. 1.

According to the present invention, the intensity of the laser beam emitted from the light emitting surface 12 is rendered larger than the intensity of the laser beam emitted from the light reflecting surface 13. For this purpose, the second dielectric film 15 of the light reflecting surface 13 is so formed as to have reflectance higher than that of the first dielectric film 14 of the light emitting surface 12. The inventor of the present invention has found out from various experiments that an interface between the light emitting surface 12 and the first dielectric film 14 and an interface between the light reflecting surface 13 and the second dielectric film 15 are oxidized when the laser device is operated for a long time. Ga atoms are likely to be an uppermost layer on the (0001) plane having the Ga-polarity, and N atoms are likely to be an uppermost layer on the (000-1) plane having the N-polarity reversed thereto and hence the (000-1) plane is unlikely to be oxidized as compared with the (0001) plane. Consequently, the (000-1) plane is employed as the light emitting surface 12, whereby the light emitting surface 12 of the laser beam can be inhibited from deterioration due to oxidation and hence stable laser characteristics can be obtained for a long time.

In order to attain a high power laser device, dielectric films made of oxide films such as Al₂O₃ or SiO₂ are stacked on the light emitting surface 12 and the light reflecting surface 13, whereby generally controlling reflectance. Two layers having different refractive indices are alternately stacked on the light reflecting surface 13, so that reflectance toward inside the laser element can be increased. Thus, while the intensity of light on the light emitting surface 12 can be increased, increase in the light intensity disadvantageously facilitates oxidation of the light emitting surface 12 through photochemical reaction. This photochemical reaction is likely to be caused by short wavelength of the laser beam and hence becomes a serious problem for the nitride-based semiconductor laser device 100. According to the present invention, however, the (000-1) plane, unlikely to be oxidized as compared with the (0001) plane is employed as the light emitting surface 12 having a large light intensity, whereby the nitride-based semiconductor laser device 100 allowing stable operation can be attained even when the nitride-based semiconductor laser device 100 is operated for a long time in a high power operation at 100 mW or more, for example.

A fluoride film such as CaF₂ or a nitride film such as AlN containing no oxygen is employed as the layer in contact with a semiconductor, whereby oxidation on the interface between the semiconductor and the film stacked on the semiconductor can be suppressed. Thus, the nitride-based semiconductor laser device 100 allowing further stable operation in a high power operation of 100 mW for example can be attained.

The first dielectric film 14 formed on the surface of the light emitting surface 12 may be formed by a single layer or a multiple layer, or preferably formed by three layers. Thus, oxidation of the light emitting surface 12 can be easily suppressed. When the total number of the first dielectric film 14 formed on the surface of the light emitting surface 12 is excessive, on the other hand, reflectance is increased and hence an high power operation becomes disadvantageously difficult. Additionally, control of the reflectance and securement of reproducibility become difficult and yield of the nitride-based semiconductor laser device 100 can be disadvantageously reduced.

The second dielectric film 15 formed on the surface of the light reflecting surface 13 is preferably formed by a multilayer film so as to have high reflectance. When the total number of the second dielectric film 15 formed on the surface of the light reflecting surface 13 is excessive, however, control of the reflectance and securement of reproducibility become difficult similarly to the light emitting surface 12. Distortion between the semiconductor and the reflective film formed by the second dielectric film 15 is increased and hence defects such as separation of the second dielectric film 15 tends to occur. Therefore, the second dielectric film 15 formed on the surface of the light reflecting surface 13 is most preferably formed by at least 5 layers and not more than 17 layers. It is preferable to clean surfaces of the light emitting surface 12 and the light reflecting surface 13 by plasma treatment in a vacuum apparatus in advance of a step of forming the first dielectric film 14 and the second dielectric film 15 on the light emitting surface 12 and the light reflecting surface 13 respectively and then to form the aforementioned first dielectric film 14 and second dielectric film 15. Thus, a native oxide film formed on the light emitting surface 12 and the light reflecting surface 13 can be removed during from formation of the light emitting surface 12 and the light reflecting surface 13 until formation of the first dielectric film 14 and the second dielectric film 15.

Nitrogen is most preferable as gas employed in the aforementioned plasma treatment. Thus, the light emitting surface 12 of the (000-1) plane in which N atoms are likely to be the uppermost layer can become further nitrogen-rich layer and hence the light emitting surface 12 can be inhibited from oxidation even when the nitride-based semiconductor laser device 100 is operated for a long time.

The substrate 1 may be a growth substrate or a support substrate. When the substrate 1 is the growth substrate, the substrate 1 is formed by a nitride-based semiconductor substrate or a substrate made of a material other than nitride-based semiconductor. A a —SiC, ZnO, sapphire, spinel, or LiAlO₃ substrate having a hexagonal structure or a rhombohedral structure may be employed as the substrate made of the material other than nitride-based semiconductor, for example. On the other hand, the nitride-based semiconductor substrate is preferably employed in order to obtain a nitride-based semiconductor layer (semiconductor laser element portion 11) having the most excellent crystallinity.

When the nitride-based semiconductor substrate, the α-SiC substrate or the ZnO substrate is employed as the substrate 1, the emission layer 4 whose plane orientation identical with the plane orientation of the growth substrate is the main surface can be formed on the growth substrate (substrate 1) by employing the substrate whose plane orientation is the substantially (H, K, −H−K, 0) plane such as a (11-20) plane or a (1-100) plane. When at least one of the light emitting surface 12 and the light reflecting surface 13 is formed by cleavage, the plane orientation of the growth substrate is preferably in the range of about ±0.3 degrees from the (H, K, −H−K, 0) plane. When the both of the light emitting surface 12 and the light reflecting surface 13 are formed by the method other than etching, polishing or cleavage such as selective growth, the plane orientation of the growth substrate is preferably in the range of ± about 25 degrees from the (H, K, −H−K, 0) plane. When the sapphire substrate is employed as the substrate 1, the substrate whose plane orientation is a (1-102) plane is employed, whereby the emission layer 4 having the (1-100) plane as the main surface can be formed on the growth substrate.

When a γ-LiAlO₃ is employed as the substrate 1, the emission layer 4 having the (1-100) plane as the main surface is formed on the growth substrate by employing the substrate whose plane orientation is a (100) plane. When an electrically conductive growth substrate is employed as the substrate, an electrode layer (not shown) may be formed on a surface of the growth substrate, opposite to a side on which the semiconductor layer (semiconductor laser element portion 11) is bonded. When the semiconductor is the growth substrate, the first semiconductor layer 2 may have the same conductivity type as the conductivity type of the growth substrate.

When the support substrate is employed as the substrate 1, the support substrate (substrate 1) and the semiconductor laser element portion 11 are bonded to each other through solder. The support substrate (substrate 1) may be an electrically conductive substrate or an insulating substrate. A metal plate such as Cu—W, Al and Fe—Ni or a semiconductor substrate such as single-crystalline Si, SiC, GaAs and ZnO or a polycrystalline AlN substrate may be employed as the electrically conductive support substrate (substrate 1). Alternately, a conductive resin film in which conductive grains of a metal or the like are dispersed, a composite material of a metal and a metal oxide may be employed. A composite material of carbon and metal consisting of a graphite particle sintered body impregnated with a metal may be alternatively employed. When the electrically conductive support substrate (substrate 1) is employed, an electrode layer (not shown) may be formed on a surface of the support substrate, opposite to a side on which the semiconductor layer (semiconductor laser element portion 11) is bonded.

Embodiments embodying the aforementioned concept of the present invention will be hereinafter described with reference to the drawings.

### First Embodiment

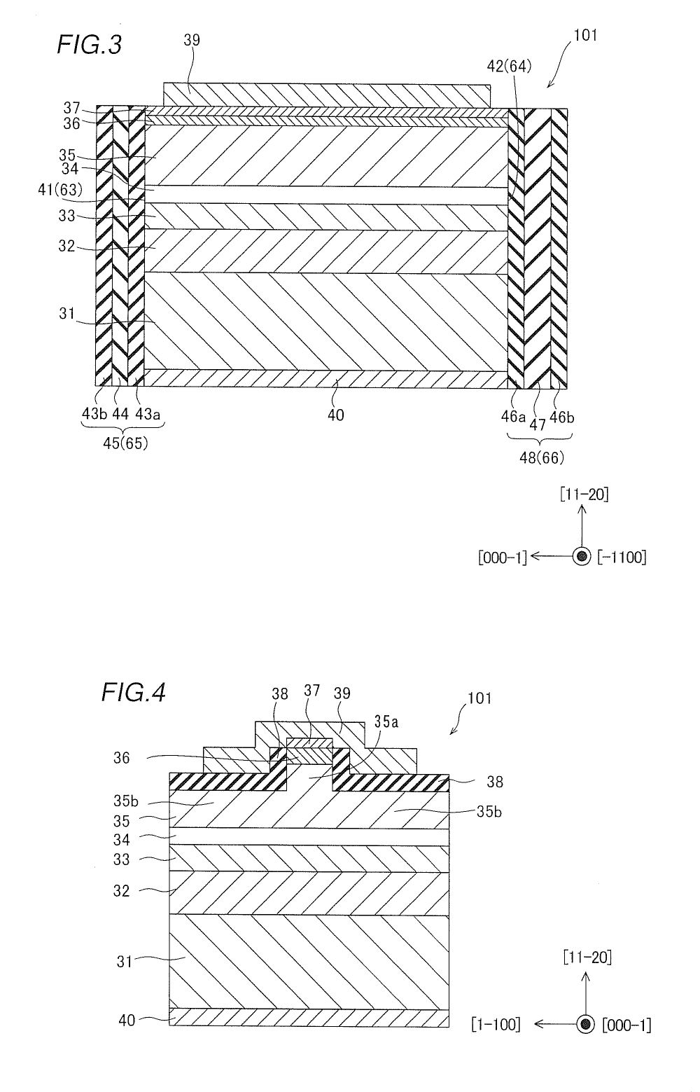

A structure of a GaN-based semiconductor laser device 101 according to a first embodiment of the present invention will be now described with reference to FIGS. 3 and 4. According to the first embodiment, the present invention is applied to the GaN-based semiconductor laser device 101 which is an exemplary nitride-based semiconductor laser device.

In the GaN-based semiconductor laser device 101 according to the first embodiment of the present invention, an n-side layer 32 having a thickness of about 100 μm and made of n-side GaN, doped with Si, having a dose of about 5×10¹⁸ cm⁻³ is formed on an n-type GaN substrate 31 having a thickness of about 100 μm, doped with Si, having a carrier concentration of about 5×10¹⁸ cm⁻³, as shown in FIGS. 3 and 4. The n-type GaN substrate 31 is an example of the “substrate” in the present invention. The n-side layer 32 is an example of the “nitride-based semiconductor element layer” in the present invention. According to the first embodiment, the n-type GaN substrate 31 has a misorientation angle by about 0.3 degrees from the (11-20) plane toward a [000-1] direction. A (11-20) just substrate or a substrate having a large misorientation angle (about 7 degrees, for example) may be employed. The most preferable misorientation angle is 0.05 degrees to 0.3 degrees. Grooves (depth: about 0.5 μm, width: about 20 μm) (not shown) extending in the [0001] direction are previously formed on an upper surface of the n-type GaN substrate 31. These grooves are so formed as to be located on both side portions of the GaN-based semiconductor laser device 101. An n-type cladding layer 33 having a thickness of about 400 nm and made of n-type Al_{0.07}Ga_{0.93}N, doped with Si, having a dose of about 5×10¹⁸ cm⁻³ and a carrier concentration of about 5×10¹⁸ cm⁻³ is formed on an upper surface of the n-side layer 32.

An emission layer 34 is formed on an upper surface of the n-type cladding layer 33. The emission layer 34 is formed by an n-type carrier blocking layer, an n-type light guide layer, a multiple quantum well (MQW) active layer formed by alternately stacking barrier layers and well layers, a p-type light guide layer and a p-type carrier blocking layer. More specifically, the n-type carrier blocking layer having a thickness of about 5 nm and made of n-type Al_{0.16}Ga_{0.84}N, doped with Si, having a dose of about 5×10¹⁸ cm⁻³ and a carrier concentration of about 5×10¹⁸ cm⁻³ is formed on an upper surface of the n-type cladding layer 33. The n-type light guide layer having a thickness of about 100 nm and made of n-type GaN, doped with Si, having a dose of about 5×10¹⁸ cm⁻³ and a carrier concentration of about 5×10¹⁸ cm⁻³ is formed on an upper surface of the n-type carrier blocking layer.

The MQW active layer is formed on an upper surface of the n-type light guide layer. This active layer has an MQW structure in which the four barrier layers of undoped In_{0.02}Ga_{0.98}N having a thickness of about 20 nm and the three well layers of undoped In_{0.15}Ga_{0.8}N having a thickness of about 3 nm are alternately formed.

The p-type light guide layer having a thickness of about 100 nm and made of p-type GaN, doped with Mg, having a dose of about 4×10¹⁹ cm⁻³ and a carrier concentration of about 5×10¹⁷ cm⁻³ is formed on an upper surface of the active layer. The p-type carrier blocking layer having a thickness of about 20 nm and made of p-type Al_{0.16}Ga_{0.84}N, doped with Mg, having a dose of about 4×10¹⁹ cm⁻³ and a carrier concentration of about 5×10¹⁷ cm⁻³ is formed on the p-type light guide layer.

A p-type cladding layer 35 having a projecting portion 35a and planar portions 35b other than the projecting portion 35a and made of p-type Al_{0.07}Ga_{0.93}N, doped with Mg, having a dose of about 4×10¹⁹ cm⁻³ and a carrier concentration of about 5×10¹⁷ cm⁻³ is formed on an upper surface of the emission layer 34. The planar portions 35b of the p-type cladding layer 35 each have a thickness of about 100 nm. The height from the planar portions 35b to the projecting portion 35a of the p-type cladding layer 35 is about 320 nm and the width of the projecting portion 35a is about 1.75 μm.

A p-type contact layer 36 having a thickness of about 10 nm and made of p-type In_{0.02}Ga_{0.98}N, doped with Mg, having a dose of about 4×10¹⁹ cm⁻³ and a carrier concentration of about 5×10¹⁷ cm⁻³ is formed on an upper surface of the projecting portion 35a of the p-type cladding layer 35. A ridge portion is formed by the p-type contact layer 36 and the projecting portion 35a of the p-type cladding layer 35. A lower portion of the ridge portion has a width of about 1.75 μm and is formed in a shape extending in the [0001] direction. An optical waveguide extending in the [0001] direction is formed on a portion including the emission layer 34 located below the ridge portion. The n-type cladding layer 33, the emission layer 34, the p-type cladding layer 35 and the p-type contact layer 36 are each an example of the “nitride-based semiconductor element layer” in the present invention.

A p-side ohmic electrode 37 constituted by a Pt layer having a thickness of about 5 nm, a Pd layer having a thickness of about 100 nm and an Au layer having a thickness of about 150 nm from the lower layer toward the upper layer is formed on the p-type contact layer 36 constituting the ridge portion. Current blocking layers 38 made of a SiO₂ film (insulating film), each having a thickness of about 250 nm are formed on regions other than an upper surface of the p-side ohmic electrode 37. A p-side pad electrode 39 made of a Ti layer having a thickness of about 100 nm, a Pd layer having a thickness of about 100 nm and an Au layer having a thickness of about 3 μm from the lower layer toward the upper layer is formed on prescribed regions of the current blocking layers 38, so as to be in contact with the upper surface of the p-type ohmic electrode 37.

An n-side electrode 40 is formed on a lower surface of the n-type GaN substrate 31. This n-side electrode 40 is constituted by an Al layer having a thickness of about 10 nm, a Pt layer having a thickness of about 20 nm and an Au layer having a thickness of about 300 nm successively from a side of a lower surface of the n-type GaN substrate 31.

According to the first embodiment, a light emitting surface 41 formed by the (000-1) plane having an N-polarity formed by cleavage or etching such as dry etching is formed on one end of the optical waveguide and a light reflecting surface 42 formed by the (0001) plane having a Ga-polarity is formed on the other end of the optical waveguide, as shown in FIG. 3. According to the first embodiment, the GaN-based semiconductor laser device 101 is formed such that the intensity of a laser beam emitted from the light emitting surface 41 is larger than the intensity of a laser beam emitted from the light reflecting surface 42. The light emitting surface 41 and the light reflecting surface 42 are examples of the “front facet” and the “rear facet” in the present invention respectively.

According to the first embodiment, a multilayer dielectric film 45 having reflectance of about 5%, formed by an AlN film 43a having a thickness of about 10 nm, an Al₂O₃ film 44 having a thickness of about 85 nm and an AlN film 43b having a thickness of about 10 nm successively from a side closer to a semiconductor layer is formed on a surface of the light emitting surface 41 of the laser beam, as shown in FIG. 3. Each of the AlN films 43a and 43b is an example of the “first reflective film” in the present invention. The AlN film 43b is an example of the “first insulating film” in the present invention. The Al₂O₃ film 44 is an example of the “first oxide film” in the present invention. According to the first embodiment, a multilayer dielectric film 48 having reflectance of about 95%, formed by an AlN film 46a having a thickness of about 10 nm, a multilayer reflector 47 formed by five SiO₂ films each having a thickness of about 70 nm as low refractive index films and five TiO₂ films each having a thickness of about 45 nm as high refractive index films, and an AlN film 46b having a thickness of about 10 nm successively from a side closer to the semiconductor layer is formed on a surface of the light reflecting surface 42 of the laser beam. Each of the AlN films 46a and 46b is an example of the “second reflective film” in the present invention. The AlN film 46b is an example of the “second insulating film” in the present invention. The multilayer reflector 47 is an example of the “second oxide film” in the present invention. A fluoride film such as CaF₂ or a nitride film such as AlN containing no oxygen is employed as the first and second insulating films.

A manufacturing process for the GaN-based semiconductor laser device 101 according to the first embodiment will be now described with reference to FIGS. 3 and 4.

The n-side layer 32 (thickness: about 100 nm), the n-type cladding layer 33 (thickness: about 400 nm), the emission layer 34 (the n-type carrier blocking layer having a thickness of about 5 nm, the n-type light guide layer having a thickness of about 100 nm, the MQW active layer having a total thickness of about 90 nm, the p-type light guide layer having a thickness of about 100 nm, the p-type carrier blocking layer having a thickness of about 20 nm), the p-type cladding layer 35 (thickness of the projecting portion 35a: about 400 nm) and the p-type contact layer 36 (thickness: about 10 nm) are successively formed on the upper surface of the n-type GaN substrate 31 by metal organic vapor phase epitaxy (MOVPE). Thereafter the p-side ohmic electrode 37 (thickness: about 255 nm), the current blocking layers 38 (thickness: about 250 nm) and the p-side pad electrode 39 (thickness: about 3.2 μm) are formed after p-type conversion anneal and formation of the ridge portion. The n-side electrode 40 (thickness: about 330 nm) is formed on the lower surface of the n-type GaN substrate 31 by metal organic vapor phase epitaxy (MOVPE).

According to the first embodiment, the n-type GaN substrate 31 formed with the semiconductor laser structure is so cleaved as to form the cleavage plane of the (0001) plane, thereby forming a structure separated in the form of a bar. Thereafter a substrate formed with the cleavage planes is introduced in an electron cyclotron resonance (ECR) sputtering apparatus.

According to the first embodiment, the light emitting surface 41 formed by the cleavage plane of the (0001) plane is cleaned by applying ECR plasma to the light emitting surface 41 for five minutes. The ECR plasma is generated under a condition of microwave output of about 500 W in a nitrogen gas atmosphere of about 0.02 Pa. At this time, the light emitting surface 41 is slightly etched. At this time, RF power is not applied to a sputtering target. The semiconductor layer of the light emitting surface 41 can be made nitrogen rich through the process, and hence oxidation of the light emitting surface 41 can be conceivably suppressed when operating the GaN-based semiconductor laser device 101 for a long time. Thereafter the multilayer dielectric film 45 (see FIG. 3) is formed on the light emitting surface 41 by ECR sputtering.

According to the first embodiment, the light reflecting surface 42 formed by the cleavage plane of the (000-1) plane is cleaned by applying ECR plasma to the light reflecting surface 42 of the cleavage plane of the (000-1) plane for five minutes similarly to the aforementioned step of cleaning the light emitting surface 41. At this time, RF power is not applied to a sputtering target. The light reflecting surface 42 is slightly etched through these processes. Thereafter the multilayer dielectric film 48 is formed on the light reflecting surface 42 by ECR sputtering. Thus, the GaN-based semiconductor laser device 101 according to the first embodiment is formed.

According to the first embodiment, as hereinabove described, the GaN-based semiconductor laser device 101 comprises the light emitting surface 41 located on the forward end of the optical waveguide and formed by the substantially (000-1) plane, whereby the substantially (000-1) plane where an outermost layer is likely to a nitrogen (N) atomic layer is unlikely to become oxidized as compared with the substantially (0001) plane where an outermost layer is likely to become a gallium (Ga) atomic layer, and hence the substantially (000-1) plane employed as the main laser light emitting surface can be inhibited from deterioration due to oxidation. Thus, laser characteristics of the GaN-based semiconductor laser device 101 can be inhibited from becoming unstable.

According to the first embodiment, as hereinabove described, the GaN-based semiconductor laser device 101 comprises the AlN film 43a and the AlN film 46a made of dielectric materials, provided on surfaces of the light emitting surface 41 and the light reflecting surface 42 respectively, whereby the AlN film 43a and the AlN film 46a substantially contain no oxygen and hence the light emitting surface 41 and the light reflecting surface 42 in contact with the AlN film 43a and the AlN film 46a respectively can be inhibited from oxidation.

According to the first embodiment, as hereinabove described, the method of manufacturing the GaN-based semiconductor laser device 101 comprises a step of cleaning the light emitting surface 41 and the light reflecting surface 42, whereby native oxide films formed on the light emitting surface 41 and light reflecting surface 42 can be removed by cleaning and hence laser characteristics of the GaN-based semiconductor laser device 101 can be inhibited from becoming unstable.

According to the first embodiment, as hereinabove described, the Al₂O₃ film 44 is formed on the surface of the AlN film 43a and the AlN film 43b is formed on the surface of the Al₂O₃ film 44, whereby the multilayer dielectric film 45 having reflectance of about 5% can be formed.

According to the first embodiment, as hereinabove described, the multilayer reflector 47 is formed on the surface of the AlN film 46a and the AlN film 46b is formed on the surface of the multilayer reflector 47, whereby the multilayer dielectric film 48 having reflectance of about 95% can be formed.

### Modification of First Embodiment

A modification of the first embodiment will be now described.

According to the modification of the first embodiment, Al or In composition of AlGaN, InGaN or the like forming an n-type cladding layer 33, an emission layer 34 and a p-type cladding layer 35 is different. More specifically, while Al_{0.07}Ga_{0.93}N is employed as the n-type cladding layer 33 and the p-type cladding layer 35 according to the aforementioned first embodiment, Al_{0.03}Ga_{0.97}N is employed as the n-type cladding layer 33 and the p-type cladding layer 35 according to the modification of the first embodiment. The doses and carrier concentrations of the n-type cladding layer 33 and the p-type cladding layer 35 according to the modification of the first embodiment are similar to those of the aforementioned first embodiment.

An n-type carrier blocking layer made of n-type Al_{0.10}Ga_{0.90}N and an n-type light guide layer made of n-type In_{0.05}Ga_{0.95}N are employed as the emission layer 34 according to the modification of the first embodiment, dissimilarly to the aforementioned first embodiment. The thicknesses, doses and carrier concentrations of the n-type carrier blocking layer and the n-type light guide layer according to the modification of the first embodiment are similar to those of the aforementioned first embodiment.

An MQW active layer of the emission layer 34 according to the modification of the first embodiment has a structure obtained by alternately stacking three barrier layers made of undoped In_{0.25}Ga_{0.75}N and two well layers made of In_{0.55}Ga_{0.45}N, dissimilarly to the aforementioned first embodiment. The thicknesses of the barrier layers and the well layers according to the modification of the first embodiment are similar to those of the aforementioned first embodiment.

Additionally, a p-type carrier blocking layer made of p-type Al_{0.10}Ga_{0.90}N and a p-type light guide layer made of p-type In_{0.05}Ga_{0.95}N is employed as the emission layer 34 according to the modification of the first embodiment, dissimilarly to the aforementioned first embodiment. The thicknesses, doses and carrier concentrations of the p-type carrier blocking layer and the p-type light guide layer according to the modification of the first embodiment are similar to those of the aforementioned first embodiment.

The remaining structure of the modification of the first embodiment is similar to that of the aforementioned first embodiment.

According to the modification of the first embodiment, In composition contained in the MQW active layer is higher than that of the aforementioned first embodiment, whereby the active layer is likely to be oxidized and hence the effects of the present invention are more remarkable as compared with those of the aforementioned first embodiment. In particular, according to the modification of the first embodiment, In composition contained in the well layers of the MQW active layer is larger than Ga composition (In composition of InGaN forming the well layers exceeds 0.5), whereby the active layer is likely to be oxidized and hence the effects of the present invention are more remarkable as compared with those of the aforementioned first embodiment.

### Second Embodiment

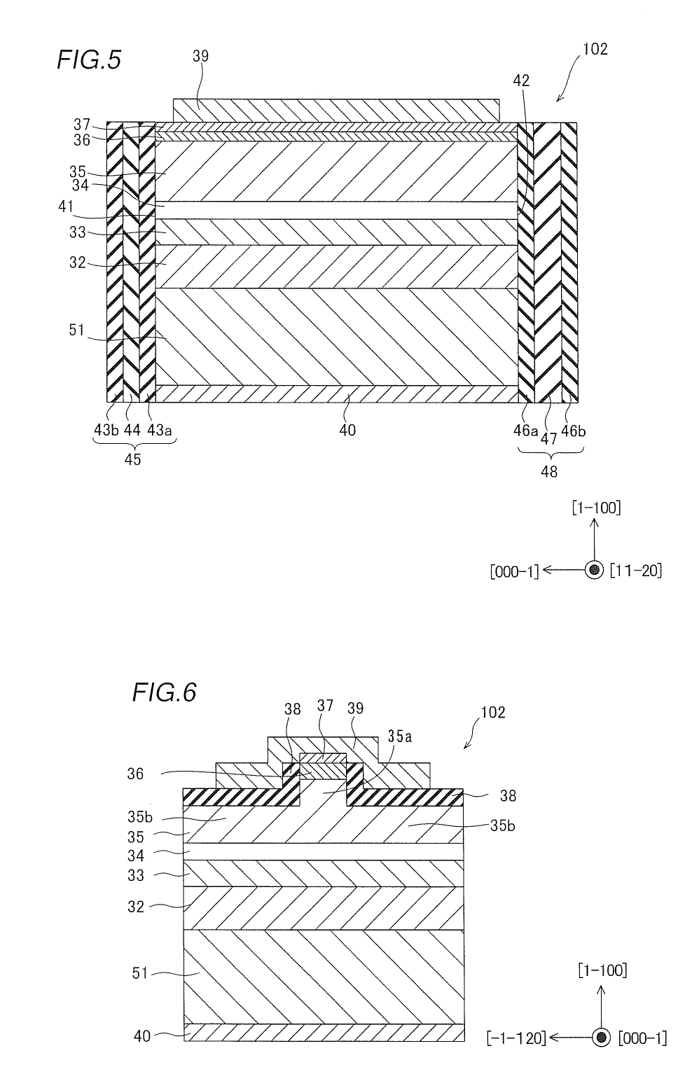

Referring to FIGS. 5 and 6, a semiconductor laser structure is formed on an n-type GaN (1-100) plane misoriented substrate 51 in a GaN-based semiconductor laser device 102 according to a second embodiment, dissimilarly to the aforementioned first embodiment.

According to the second embodiment of the present invention, the semiconductor laser structure similar to that of the first embodiment is formed on the n-type GaN (1-100) plane misoriented substrate 51 having a thickness of about 100 μm and doped with oxygen, having a carrier concentration of about 1×10¹⁸ cm⁻³, as shown in FIGS. 5 and 6.

The remaining structure of the GaN-based semiconductor laser device 102 according to the second embodiment is similar to that of the GaN-based semiconductor laser device according to the aforementioned first embodiment.

### Modification of Second Embodiment

A modification of the second embodiment will be now described.

According to the modification of the second embodiment, a structure similar to that of the aforementioned modification of the first embodiment is applied to the aforementioned second embodiment and the semiconductor laser structure similar to that of the aforementioned modification of the first embodiment is formed on an n-type GaN (1-100) plane misoriented substrate 51 having a thickness of about 100 μm and doped with oxygen, having a carrier concentration of about 1×10¹⁸ cm⁻³, as shown in FIGS. 5 and 6.

The remaining structure of the GaN-based semiconductor laser device according to the modification of the second embodiment is similar to that of the GaN-based semiconductor laser device according to the aforementioned modification of the first embodiment.

According to the modification of the second embodiment, In composition contained in a MQW active layer is higher than that of the aforementioned second embodiment, whereby the active layer is likely to be oxidized and hence the effects of the present invention are more remarkable as compared with those of the aforementioned second embodiment. In particular, according to the modification of the second embodiment, In composition contained in the well layers of the MQW active layer is larger than Ga composition (In composition of InGaN forming the well layers exceeds 0.5), whereby the active layer is likely to be oxidized and hence the effects of the present invention are more remarkable as compared with those of the aforementioned second embodiment.

### Third Embodiment

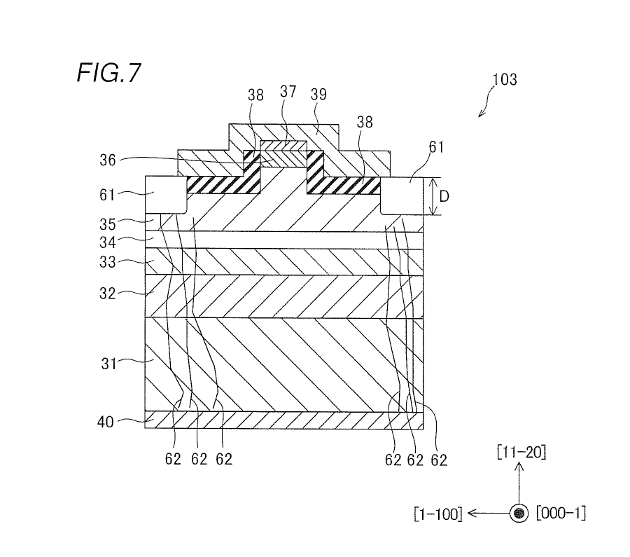

A structure of a GaN-based semiconductor laser device 103 according to a third embodiment, provided with irregular irregularities 62 on regions other than regions formed with an optical waveguide of a light emitting surface 63 and a light reflecting surface 64 will be described with reference to FIG. 7, dissimilarly to the aforementioned first embodiment.

As shown in FIG. 7, grooves 61 for forming the GaN-based semiconductor laser device 103 by cleavage, each having a depth D of about 1 μm to about 100 μm are formed on ends of the p-type cladding layer 35 and the current blocking layers 38 of the GaN-based semiconductor laser device 103. The irregular irregularities 62 are formed on the regions other than the regions formed with the optical waveguide of the light emitting surface 63 (see FIG. 3) and the light reflecting surface 64 (see FIG. 3).

The remaining structure of the third embodiment is similar to that of the aforementioned first embodiment.

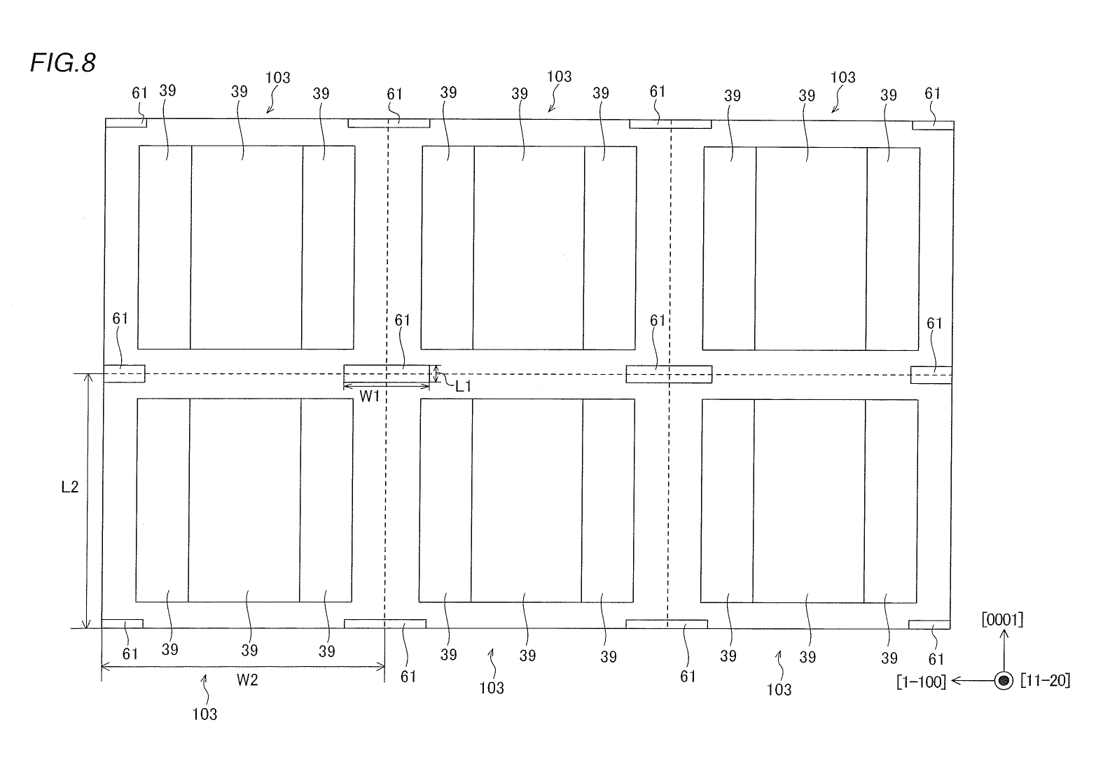

A Step of preparing the GaN-based semiconductor laser device 103 according to the third embodiment by cleavage will be now described with reference to FIGS. 7 and 8.

FIG. 8 shows six GaN-based semiconductor laser devices 103 formed on a wafer through a manufacturing process similar to that of the aforementioned embodiment.

As shown in FIG. 8, the grooves 61 each having the depth D (see FIG. 7) of about 1 μm to about 100 μm, a length L1 of about 1 μm to about 10 μm and a width W1 of about 20 μm to about 150 μm are formed from an upper surface of the wafer (upper surfaces of the GaN-based semiconductor laser devices 103) in a period similar to the device size of the GaN-based semiconductor laser device 103 by laser scribing. In this case, the conditions of the laser scribing are a laser wavelength of about 355 nm, laser power of about 200 mW to about 250 mW and a scanning speed of about 2 mm/sec. to about 10 mm/sec. Each GaN-based semiconductor laser device 103 is so formed as to have a width W2 of about 200 μm and a length L2 of about 400 μm. The length L2 of the GaN-based semiconductor laser device 103 can be increased as the width W2 is increased. However, when the maximum value of a scribing width is Wₘₐₓ, the width 2 of the GaN-based semiconductor laser device 103 is preferably 50≦W2−Wₘₐₓ≦150. Each groove 61 is preferably formed in a V-shape such that the area of the bottom portion of the groove 61 is reduced toward a direction of the depth D (see FIG. 7). Thus, such a shape can facilitate cleavage with excellent yield.

After forming a plurality of the grooves 61, cleavage planes formed by a substantially (000-1) plane and a substantially (0001) plane can be formed by cleaving along a broken line parallel to a substantially [1-100] direction as shown in FIG. 8. At this time, the irregularities 62 (see FIG. 7) are formed on the regions other than the regions formed with the optical waveguide of the light emitting surface 63 and the light reflecting surface 64.

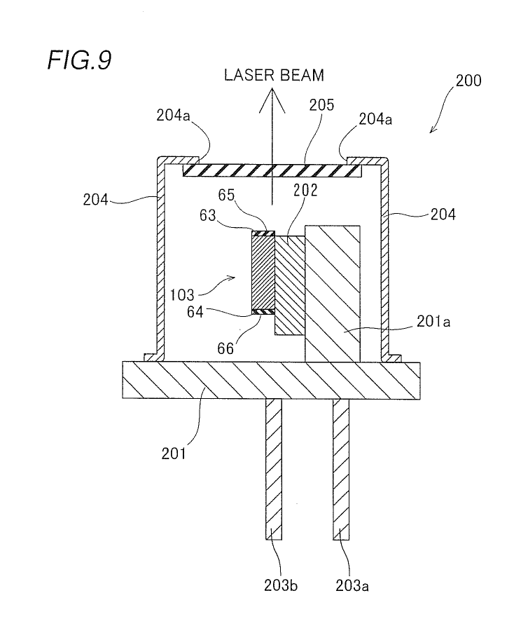

A structure of a nitride-based semiconductor laser apparatus 200 will be now described with reference to FIG. 9.

As a structure of the nitride-based semiconductor laser apparatus 200 according to the third embodiment, a stem 201 made of iron is formed integrally with a heat radiation member 201a, as shown in FIG. 9. A heat sink (submount) 202 mounted with a GaN-based semiconductor laser device 103 is mounted on the heat radiation member 201a. The GaN-based semiconductor laser device 103 is arranged such that a multilayer dielectric film 65 on the light emitting surface 63 is opposed to a cap glass 205 described below and a multilayer dielectric film 66 on the light reflecting surface 64 is opposed to the stem 201. Two leads 203a and 203b are mounted on the stem 201. The leads 203a and 203b are mounted on the stem 201 in a state of holding air tight. A cap portion 204 is bonded to the stem 201. The cap glass 205 is fusion bonded onto a region corresponding to an opening 204a of the cap portion 204.

The GaN-based semiconductor laser device 103 is airtight-sealed in a desirable gas atmosphere by the cap portion 204. In this case, when operating a high power operation of at least 100 mW, a moisture concentration in the gas airtight-sealed is preferably at most 5000 ppm. Thus, moisture in the cap portion 204 is thermally and optically activated in the high power operation, whereby end surface of the GaN-based semiconductor laser device 103 can be inhibited from oxidation.

According to the third embodiment, as hereinabove described, the irregularities 62 are provided on the regions other than the regions formed with the optical waveguide of the light emitting surface 63 and the light reflecting surface 64, whereby the surface areas of the light emitting surface 63 and the light reflecting surface 64 are increased due to the irregularities 62, whereby the oxidized degrees of the regions formed with the optical waveguide of the light emitting surface 63 and the light reflecting surface 64 can be reduced by the increased surface areas because of the finite amount of oxygen existing in the cap portion 204 when the GaN-based semiconductor laser device 103 is airtight-sealed by the cap portion 204. Thus, the GaN-based semiconductor laser device 103 can be stably operated for a long period even in the high power operation of at least 100 mW, for example.

The remaining effects of the third embodiment are similar to those of the aforementioned first embodiment.

### Modification of Third Embodiment

A modification of the third embodiment will be now described.

According to the modification of the third embodiment, a structure similar to that of the aforementioned modification of the first embodiment is applied to the aforementioned third embodiment and a GaN-based semiconductor laser device provided with irregularities 62 on regions other than regions formed with an optical waveguide of a light emitting surface 63 and a light reflecting surface 64 is formed as shown in FIG. 7, dissimilarly to the aforementioned modification of the first embodiment.

The remaining structure of the GaN-based semiconductor laser device according to the modification of the third embodiment is similar to that of the GaN-based semiconductor laser device according to the aforementioned modification of the first embodiment.

According to the modification of the third embodiment, In composition contained in a MQW active layer is higher than that of the aforementioned third embodiment, whereby the active layer is likely to be oxidized and hence the effects of the present invention are more remarkable as compared with those of the aforementioned third embodiment. In particular, according to the modification of the third embodiment, In composition contained in the well layers of the MQW active layer is larger than Ga composition (In composition of InGaN forming well layers exceeds 0.5), whereby the active layer is likely to be oxidized and hence the effects of the present invention are more remarkable as compared with those of the aforementioned third embodiment.

### Fourth Embodiment

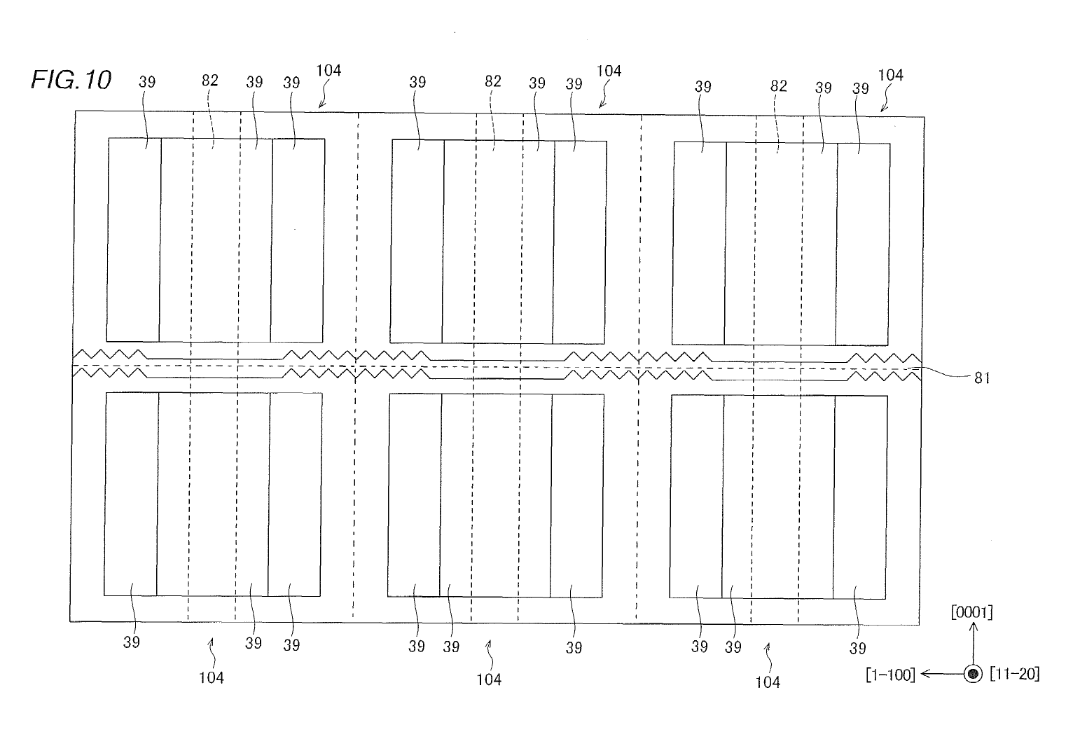

A step of preparing a GaN-based semiconductor laser device 104 according to a fourth embodiment by etching will be now described with reference to FIG. 10, dissimilarly to the aforementioned third embodiment.

As shown in FIG. 10, a mask 81 for dry etching is formed in a linear shape on regions above optical waveguides 82 and formed in an irregular shape such as a serrated shape or a corrugated shape on regions other than the regions above the optical waveguides 82, and dry etching is performed from an upper surface of a wafer, whereby the GaN-based semiconductor laser devices 104 are formed. At this time, irregularities 62 are partially formed on light emitting surfaces 63 and light reflecting surfaces 64, similarly to the third embodiment.

According to the fourth embodiment, as hereinabove described, the light emitting surfaces 63 and the light reflecting surfaces 64 are formed by etching, whereby the irregularities 62 can be easily provided on regions other than regions formed with the optical waveguides of the light emitting surfaces 63 and light reflecting surfaces 64.

The remaining effects of the fourth embodiment are similar to those of the aforementioned third embodiment.

### Modification of Fourth Embodiment

A modification of the fourth embodiment will be now described.

According to the modification of the fourth embodiment, a structure similar to that of the aforementioned modification of the first embodiment is applied to the aforementioned fourth embodiment and a GaN-based semiconductor laser device partially provided with irregularities 62 (see FIG. 7) on a light emitting surface 63 and a light reflecting surface 64 (see FIG. 3) is formed as shown in FIG. 10 dissimilarly to the aforementioned modification of the third embodiment.

According to the modification of the fourth embodiment, In composition contained in a MQW active layer is higher than that of the aforementioned fourth embodiment, whereby the active layer is likely to be oxidized and hence the effects of the present invention are more remarkable as compared with those of the aforementioned fourth embodiment. In particular, according to the modification of the fourth embodiment, In composition contained in well layers of the MQW active layer is larger than Ga composition (In composition of InGaN forming the well layers exceeds 0.5), whereby the active layer is likely to be oxidized and hence the effects of the present invention are more remarkable as compared with those of the aforementioned fourth embodiment.

Although the present invention has been described and illustrated in detail, it is clearly understood that the same is by way of illustration and example only and is not to be taken by way of limitation, the spirit and scope of the present invention being limited only by the terms of the appended claims.

For example, while the grooves are formed by laser scribing in the aforementioned third embodiment, the present invention is not restricted to this but grooves may be mechanically formed by diamond point scribing.

What is claimed is:

1. A nitride-based semiconductor laser device comprising:
an optical waveguide extending substantially parallel to a [0001] direction of a nitride-based semiconductor layer;
a front facet located on a forward end of said optical waveguide and formed by a substantially (000-1) plane of said nitride-based semiconductor layer; and
a rear facet located on a rear end of said optical waveguide and formed by a substantially (0001) plane of said nitride-based semiconductor layer, wherein
an intensity of a laser beam emitted from said front facet is rendered larger than an intensity of a laser beam emitted from said rear facet.

2. The nitride-based semiconductor laser device according to claim 1, further comprising a first reflective film and a second reflective film made of a dielectric material, provided on a surface of said front facet and a surface of said rear facet respectively, wherein
at least said first reflective film provided on said surface of said front facet substantially contains no oxygen.

3. The nitride-based semiconductor laser device according to claim 2, further comprising a first oxide film provided on said first reflective film.

4. The nitride-based semiconductor laser device according to claim 3, further comprising a first insulating film substantially containing no oxygen provided on said first oxide film.

5. The nitride-based semiconductor laser device according to claim 4, wherein
said first reflective film and said first insulating film are formed by the same member.

6. The nitride-based semiconductor laser device according to claim 2, further comprising a second oxide film provided on said second reflective film.

7. The nitride-based semiconductor laser device according to claim 2, further comprising a multilayer reflector provided on said second reflective film.

8. The nitride-based semiconductor laser device according to claim 7, further comprising a first insulating film substantially containing no oxygen provided on said multiplayer reflector.

9. The nitride-based semiconductor laser device according to claim 1, further comprising a substrate formed with said nitride-based semiconductor element layer, wherein
a plane orientation of said substrate is within a range of a prescribed angle from a (H, K, −H−K, 0) plane, where at least either one of H and K is a nonzero integer.

10. The nitride-based semiconductor laser device according to claim 9, wherein
said plane orientation is in a range of 0.05 to 0.3 degrees from a (H, K, −H−K, 0) plane

11. The nitride-based semiconductor laser device according to claim 1, wherein
irregularities are provided on regions other than regions of said front facet and said rear facet where said optical waveguide is formed.

12. The nitride-based semiconductor laser device according to claim 1, wherein
said nitride-based semiconductor element layer includes a multiple quantum well active layer containing In and Ga, and
a composition of said In is larger than a composition of said Ga.

13. The nitride-based semiconductor laser device according to claim 1, wherein
said nitride-based semiconductor laser device is airtight-sealed in an atmosphere of a moisture concentration is at most 5000 ppm.

14. A method of manufacturing a nitride-based semiconductor laser device, comprising steps of:
growing a nitride-based semiconductor element layer on a substrate;
forming an optical waveguide extending substantially parallel to a [0001] direction on said nitride-based semiconductor element layer;
forming a front facet formed by a substantially (000-1) plane of said nitride-based semiconductor layer on a forward end of said optical waveguide; and
forming a rear facet formed by a substantially (0001) plane of said nitride-based semiconductor layer on a rear end of said optical waveguide, wherein
a direction substantially perpendicular to said [0001] direction of said nitride-based semiconductor layer substantially coincides with said normal direction of said substrate, and
an intensity of a laser beam emitted from said front facet is larger than an intensity of a laser beam emitted from said rear facet.

15. The method of manufacturing a nitride-based semiconductor laser device according to claim 14, further comprising a step of providing a first reflective film and a second reflective film made of a dielectric material on a surface of said front facet and a surface of said rear facet, wherein
at least said first reflective film provided on said surface of said front facet is so formed as to substantially contain no oxygen.

16. The method of manufacturing a nitride-based semiconductor laser device according to claim 14, wherein
said step of forming said front facet and said rear facet includes a step of forming at least one of said front facet and said rear facet by etching.

17. The method of manufacturing a nitride-based semiconductor laser device according to claim 14, wherein
said step of forming said front facet and said rear facet includes a step of forming at least one of said front facet and said rear facet by cleavage.

18. The method of manufacturing a nitride-based semiconductor laser device according to claim 14, wherein
said step of growing said nitride-based semiconductor element layer on said substrate includes a step of growing said nitride-based semiconductor element layer on said substrate having a main surface inclined by a prescribed angle from a (H, K, −H−K, 0) plane (when at least either one of H and K is a nonzero integer).

19. The method of manufacturing a nitride-based semiconductor laser device according to claim 14, further comprising a step of cleaning at least one of said front facet and said rear facet.

20. The method of manufacturing a nitride-based semiconductor laser device according to claim 19,
said step of cleaning at least one of said front facet and said rear facet includes a step of cleaning at least one of said front facet and said rear facet by plasma treatment.
